(19) United States
(12) Patent Application Publication
(10) Pub. No.: US 2011/0273031 A1
(43) Pub. Date: Nov. 10, 2011

(54) BUSHING EXPLOSION CONTAINMENT DEVICE AND METHOD OF USING THE SAME

(76) Inventors: Jeffrey A. Spoljarick, North Huntington, PA (US); Andrew P. Sebek, Acme, PA (US); Joseph H. LaCarte, Belle Vernon, PA (US); Bart A. Gaskey, New Staton, PA (US)

(21) Appl. No.: 12/811,283

(22) PCT Filed: Jan. 9, 2009
(86) PCT No.: PCT/US09/30574

§ 371 Date: Apr. 28, 2011

Related U.S. Application Data
(60) Provisional application No. 61/020,321, filed on Jan. 10, 2008.

(51) Int. Cl. H02H 11/00; H05K 13/00

(52) U.S. Cl. 307/326; 29/825

(57) ABSTRACT

A method and device prevents injuries when performing maintenance on a circuit breaker including a body portion and one or more outwardly extending bushings having terminals at the ends thereof for connection to power lines. The circuit breaker is first de-energizing. A cover is provided and wrapped around one or more of the circuit breaker bushings in a manner leaving the bushing terminal exposed. The cover is secured and will prevent escape of at least some fragmented materials in the event of a bushing explosion.

### CROSS REFERENCE TO RELATED APPLICATION

This application claims the benefit of U.S. provisional patent application No. 60/020,321 filed on Jan. 10, 2008 and entitled Sub-Station Applied Insulator Containment Device, which is hereby incorporated by reference in its entirety

### TECHNICAL FIELD

This invention is generally related to sub-station personnel protective devices for pressurized bushings.

### BACKGROUND

High voltage circuit breakers, such as the one shown in FIG. 1, generally include a body portion 2 and outwardly extending bushings 3. The ends of the bushings 3 include one or more terminals 4 that are coupled to electrical power lines 5. Within the body portion 2 the circuit breaker mechanism selectively electrically connects or disconnects internal contacts.

Commonly, the body portion 2 and bushings 3 contain an arc resisting gas under pressure. The gas is used primarily to prevent arcing between internal contacts. Typically, the body portion 2 of the circuit breaker is made of a metallic material and the bushings are made of a non-conducting, non-metallic material. Often times, the bushing is made of porcelain or other brittle non-conducting material. While bushings of this type are corrosion resistant and effective insulators, the use of the brittle material can pose a safety concern to service personnel when performing maintenance. In particular, if the structural integrity of the bushing 3 is compromised, the pressure of the internal gas could cause the bushing 3 to explode. Any service personnel near-by could be seriously injured by the potentially lethal projectiles. Standards relating to safety include ANSI/AIHA Z10-2005, Section 5 paragraph 5.1.1, Hierarachy of controls and OSHAS 18001-2007, Section 4, paragraph 4.3.1, Hazard identification, risk assestment and determining controls.

Thus, there is a need in the art for a protective device that prevents service person injuries due to exploding bushings.

### SUMMARY OF THE INVENTION

According to one aspect of the present invention, a method is provided for preventing injuries when performing maintenance on a circuit breaker including a body portion and one or more outwardly extending bushings having terminals at the ends thereof for connection to power lines. The method includes de-energizing the circuit breaker. A cover is then provided having a top edge, a bottom edge, a first side edge and a second side edge. The cover is wrapped around at least one bushing, wherein at least a portion of the cover overlaps, and the terminal remains at least partially exposed. The cover is radially constrained to prevent unwrapping. If the bushing explodes, releasing fragmented materials, the cover prevents escape of at least some of the fragmented materials.

According to another aspect of the present invention, a device is provided for preventing injuries when a circuit breaker bushing explodes, projecting fragments outwardly therefrom. The device includes a cover having a top edge, a bottom edge, a first side edge and a second side edge. A plurality of lateral straps are secured to the cover, spaced from each other and oriented parallel to the top edge. Each lateral strap includes at least one fastener for securing one end of the lateral strap to the opposed end of the same lateral strap. The cover, when wrapped around the bushing, contains at least some of the fragments of the exploding bushing.

### BRIEF DESCRIPTION OF THE FIGURES

FIG. 1 is an exemplary sub-station high voltage breaker.

FIG. 2 is an elevated view of the safety device according to the present invention in the unwrapped configuration.

FIG. 3 is an elevated view of the safety device of FIG. 2 in the wrapped configuration.

FIG. 4 is an elevated view of the safety device of FIG. 2 showing the opposed side of the wrapped configuration.

FIG. 5 is a perspective view of the safety device of FIG. 2 partially installed on the bushing of a high voltage circuit breaker.

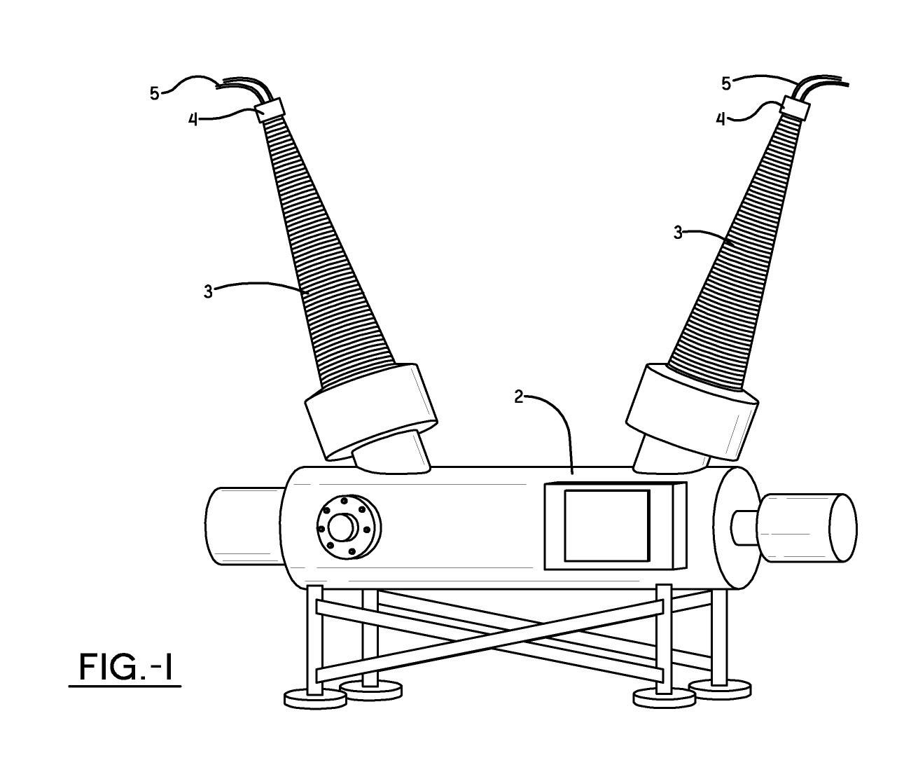

### DETAILED DESCRIPTION OF THE INVENTION

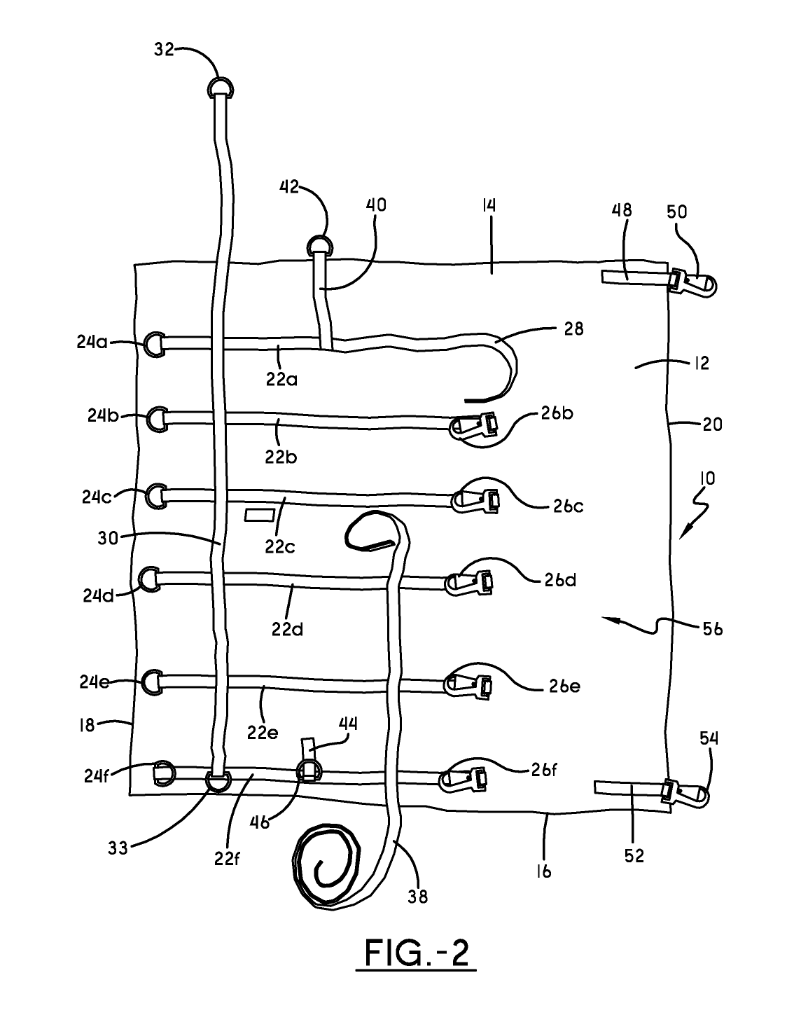

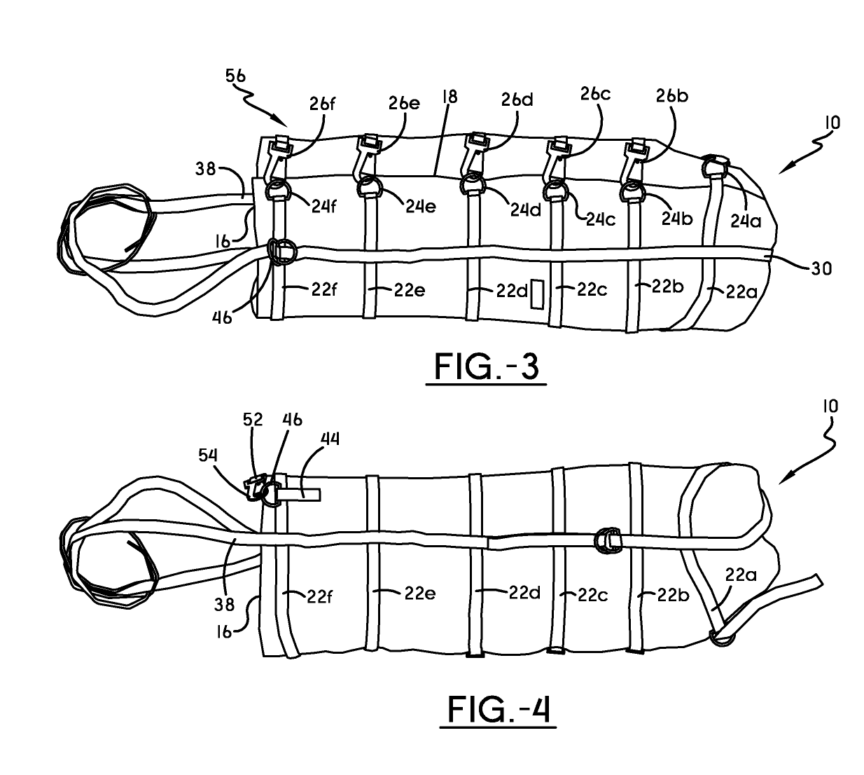

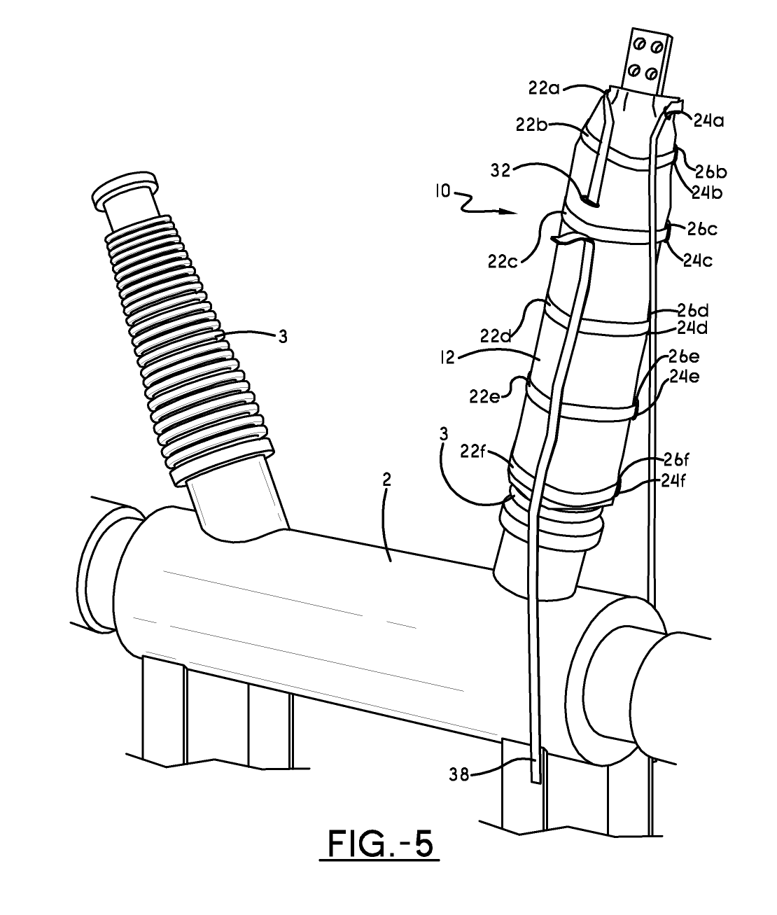

Referring now to FIG. 2, a safety device is shown and generally indicated by the numeral 10. Device 10 includes a generally square or rectangular cover 12. In one or more embodiments, cover 12 is a thin (relative to the length and width) fabric material. In a particularly preferred embodiment, cover 12 may be Kevlar fabric. The Kevlar may be, for example, a three layer 3000 denier with a break strength of 1,800 lb/inch. In any event, once installed, cover 12 must be strong enough to withstanding the force of an exploding insulator and contain the outwardly projecting pieces thereof.

Device 10 includes a top edge 14 and a bottom edge 16 that are joined by a first side edge 18 and a second side edge 20. A plurality of laterally extending straps 22a-f are secured to cover 12 at spaced intervals. In one embodiment six straps 22 are provided and are spaced ten inches apart. It should be appreciated, however, that the particular number and spacing of lateral straps 22 may vary depending on the size of the bushing being covered. Lateral straps 22 are attached to cover 12 with stitching, though other fastening methods may be used, such as, for example, adhesives.

Proximate to first side edge 18, D-rings 24a-f are secured to the end of each lateral straps 22a-f. As will be further understood hereinafter, in the present embodiment, two D-rings 24a are provided at lateral strap 22a. The end of lateral strap 22 opposed from D-ring 24 does not extend all the way to second side edge 20. In one or more embodiments, the lateral strap 22 extends from first side edge 18 to about ⅗ of the lateral length of cover 12. Snap hooks 26b-f are secured to the end of lateral straps 22b-f opposed from D-rings 24. As will become apparent, when installed over a bushing, snap hooks 26 are adapted to selectively engage and couple to D-rings 24. In one or more embodiments, all straps of the present invention are two inches thick with a 12,000 lb failure strength. In these or other embodiments, the engaged D-ring 24 and snap hook 26 have a failure strength of 5,000 lbs. The end of lateral strap 22a opposite of D-ring 24a does not include a snap hook, and includes an extended portion 28 that extends beyond straps 24b-f, closer to second side edge 20.

Device 10 includes a longitudinally extending strap 30 that extends upwardly from bottom edge 16 and traverses each laterally extending strap 22. The top end of longitudinally extending strap 30 extends beyond top edge 14. Two D-rings 32 are secured to the top end of longitudinal strap 30 and two D-rings 33 are secured to the bottom end of longitudinal strap 30. Longitudinally extending strap 30 is parallel to, and laterally offset from first side edge 18. In one or more embodiments, longitudinally extending strap 30 is offset from first side edge 18 by about ⅙ the total lateral width of cover 12.

A second longitudinally extending strap 34 also runs parallel to first side edge 18 and is offset therefrom. In one or more embodiments, second longitudinally extending strap 34 is offset by about ½ the total lateral width of cover 12. Second longitudinally extending strap 34 is secured to cover 12 from a point proximate to bottom edge 16 to a point approximately half way between bottom edge 16 and top edge 14. In one embodiment, second longitudinal strap 34 is secured to lateral straps 22d-f and to the portions of cover 12 therebetween. A top portion 36 of second lontigudinally extending strap 34 is not secured to either cover 12 or lateral strap 22. Likewise, a bottom portion 38 of second longitudinally extending strap 34 is not secured to either cover 12 or lateral strap 22, and extends beyond bottom edge 16. As seen in FIG. 2, bottom portion 38 is substantially longer than top portion 36.

Device 10 includes a third longitudinally extending strap 40 positioned proximate to top edge 14. In one embodiment, third longitudinally extending strap 40 extends from top edge 14 to lateral strap 22a. A D-ring 42 is secured to the top end of third longitudinally extending strap 40, proximate to top edge 14. Device 10 includes a fourth longitudinally extending strap 44 positioned proximate to bottom edge 14. In one embodiment, fourth longitudinally extending strap 44 extends from a point between lateral strap 22e and terminates on lateral strap 22f. A D-ring 46 is secured to the bottom end of fourth longitudinally extending strap 44, proximate to bottom edge 16.

Finally, device 10 includes a top strap 48 that extends laterally proximate to top edge 14 and second side edge 20. A top snap-hook 50 is secured to top strap 48 and extends laterally beyond second side edge 20. A bottom strap 52 extends laterally proximate to bottom edge 16 and second side edge 20. A bottom snap-hook 54 is secured to bottom strap 52 and extends laterally beyond second side edge 20.

Protective device 10 is used to protect service personnel in the following exemplary manner. If the circuit breaker is active and resides in a sub-station, the circuit breaker must first be de-energized. All switches must be opened and grounded properly. Next, maintenance personnel may use a man-lift, scaffolding or other approved method to reach a desired installation height. Next, the protective device 10 is installed around the bushing 3 according to the method described hereinafter. The maintenance personnel may then perform mechanical testing of the circuit breaker in accordance with maintenance procedures of the manufacturer. Once testing and maintenance is completed, the protective device is then removed and the breaker may be re-energized.

Protective device 10 may be installed according to the following method. Device 10 is positioned near the bushing 3 with top edge 14 located proximate to terminal 4 and bottom edge positioned proximate to body portion 2. Beginning with second side edge 20, the cover 12 is wrapped around the bushing 3 so that the cover 12 overlaps a substantial portion of unstrapped area 56 between snap-hooks 26 and second side edge 20. In conjunction therewith the various fasteners are connected according to the following method. D-ring 42 is attached to top snap hook 50. Next, D-rings 24a receives extended portion 28 so that strap 24a may be cinched tightly around bushing 3 in an adjustable manner. Next, snap-hooks 26b-f are secured to b-rings 24b-f respectively. Next bottom snap-hook 54 is secured to D-ring 46. D-rings 32 then receive top portion 36 in an adjustable, cinching manner. Finally, bottom portion 38 is wrapped around body portion 2 and is received in D-rings 33 in an adjustable, cinching manner.

In this manner, lateral straps 22 provide the radial support in the event of an explosion, to prevent the unwrapping of cover 12. First longitudinal strap 30 loops over the top of the bushing and second longitudinal strap extends around body portion 2 to ensure proper longitudinal positioning of the cover 12. The resulting device surrounds substantially the entire bushing, wherein only the terminals 4 extend above device 10. Because device 10 is wrapped around the bushing 3, high tension wires 5 may remain connected to contact 4 during installation and removal of device 10. Thus, in addition to the above exemplary use, device 10 of the present invention may be used for circuit breaker transportation, installation, commissioning, storage and maintenance.

The present invention protects maintenance personnel from potentially hazardous flying debris. The device 10 will not prevent a explosion, but will limit or contain a bushing explosion in a manner that allows the controlled escape of high pressure and porcelain fragments to escape at the top and bottom of the device 10. Further, device 10 may be installed on presently installed breakers without the need to disconnect, for example, the high voltage line 5 from terminals 4.

It is to be understood that the description of the foregoing exemplary embodiment(s) is (are) intended to be only illustrative, rather than exhaustive, of the present invention. Those of ordinary skill will be able to make certain additions, deletions, and/or modifications to the embodiment(s) of the disclosed subject matter without departing from the spirit of the invention or its scope, as defined by the appended claims.

We claim:

1. A method of preventing injuries when performing maintenance on a circuit breaker including a body portion and one or more outwardly extending bushings having terminals at the ends thereof for connection to power lines, the method comprising:
de-energizing the circuit breaker;
providing a cover having a top edge, a bottom edge, a first side edge and a second side edge;
wrapping said cover around at least one bushing, wherein at least a portion of said cover overlaps, and said terminal remains at least partially exposed;
radially constraining said cover to prevent unwrapping; and
wherein if said bushing explodes, releasing fragmented materials, said cover prevents escape of at least some of the fragmented materials.

2. The method of claim 1 wherein said cover comprises a Kevlar fabric.

3. The method of claim 1 wherein said cover comprises a three layer 3000 denier having a break strength of at least 1,800 lb/inch.

4. The method of claim 1 wherein said cover is substantially square shaped.

5. The method of claim 1 wherein said step of radially constraining said cover further comprises securing a plurality of straps around said cover.

6. The method of claim 5 wherein said plurality of straps each have a failure strength of at least 12,000 lb.

7. The method of claim 1 further comprising longitudinally constraining said cover.

8. The method of claim 7 wherein said cover includes at least one longitudinal strap secured thereto and parallel to said first side edge, said step of longitudinally constraining said cover comprising wrapping said longitudinal strap around said body portion.

9. A device for preventing injuries when a circuit breaker bushing explodes, projecting fragments outwardly therefrom, the device comprising:
a cover having a top edge, a bottom edge, a first side edge and a second side edge;
a plurality of lateral straps secured to said cover, spaced from each other and oriented parallel to said top edge, each said lateral strap including at least one fastener for securing one end of said lateral strap to the opposed end of said lateral strap;
wherein said cover, when wrapped around the bushing, contains at least some of the fragments.

10. A device according to claim 9 wherein said cover comprises a fabric material having a break strength of at least 1,800 lb/inch.

11. A device according to claim 9 wherein said lateral straps are secured to said cover from proximate said first side edge to approximately three fifths of the length of said top edge.

12. A device according to claim 9 wherein said fabric material comprises Kevlar.

13. A device according to claim 9 wherein said plurality of straps each have a failure strength of at least 12,000 lb.

14. A device according to claim 9 further comprising a first longitudinal strap, oriented parallel to said first side edge, and a second longitudinal strap, oriented parallel to said first side edge and spaced from said first longitudinal strap.

15. A device according to claim 14 wherein said first longitudinal strap includes a top end and a bottom end, and said second longitudinal strap includes a top end and a bottom end, said first longitudinal strap top end being adapted to fasten to said second longitudinal strap top end, and said first longitudinal strap bottom end being adapted to fasten to said second longitudinal strap bottom end.

16. A device according to claim 1 wherein said first longitudinal strap is spaced from said first side edge by about one sixth the length of said top edge and said second longitudinal strap is spaced from said first side edge by about one half the length of said top edge.
